(19) United States
(12) Patent Application Publication
(10) Pub. No.: US 2026/0360459 A1
(43) Pub. Date: Nov. 12, 2026

(54) SEMICONDUCTOR DEVICE AND METHOD FOR CONTROLLING THE SAME

(71) Applicant: Renesas Electronics Corporation, Tokyo (JP)

(72) Inventors: Shota OKAYAMA, Tokyo (JP); Akihiko KANDA, Tokyo (JP); Hirofumi HEBISHIMA, Tokyo (JP); Yohei SATO, Tokyo (JP)

(21) Appl. No.: 19/632,542

(22) Filed: Mar. 30, 2026

(30) Foreign Application Priority Data
May 12, 2025 (JP) 2025-079945

(51) Int. Cl. G11C 29/52; G11C 11/16; G11C 29/00

(52) U.S. Cl. CPC G11C 29/52; G11C 11/1675; G11C 11/1693; G11C 29/702

(57) ABSTRACT

A semiconductor device according to one embodiment includes a storage unit in which MRAM cells are arranged, an MRAM controller configured to transmit a read command and a write command to the storage unit, a chip controller configured to transmit a read request and a write request to the MRAM controller, and an ECC controller configured to determine whether data read from the storage unit has an ECC error and to perform error correction on the data. When the data read from a read address specified by the read request has the ECC error, the MRAM controller selectively performs refresh processing of writing back the data after error correction on the read address.

### CROSS-REFERENCE TO RELATED APPLICATIONS

The disclosure of Japanese Patent Application No. 2025-079945 filed on May 12, 2025 including the specification, drawings and abstract is incorporated herein by reference in its entirety.

### Background

The present disclosure relates to a semiconductor device and a method for controlling the same, and particularly relates to a semiconductor device having a magnetoresistive random access memory (MRAM) and a method for controlling the same.

### A technique listed below is disclosed

[Non-Patent Document 1] 15.9 A 16nm 16Mb Embedded STT MRAM with a 20 ns Write Time, a 1012 Write Endurance and Integrated Margin Expansion Schemes, K.F. Lin et al., ISSCC 2024 STUDY SESSION

In a semiconductor device including an MRAM in which MRAM (Magnetoresistive Random Access Memory) cells are arranged in a grid pattern as a storage device, a data error in which a bit of data held in an MRAM cell is inverted may occur. In order to recover from such an error, in the semiconductor device including MRAM, a refresh processing is performed in which errors in data where errors have occurred are corrected for the MRAM, and the error-corrected data is written back. An example of a technique related to such refresh processing is disclosed in Non-Patent Document 1.

The semiconductor device disclosed in Non-Patent Document 1 is a semiconductor device having RAM-like MRAM cells, and employs a refresh function widely used in DRAM, thereby frequently refreshing an entire memory area at regular intervals.

### SUMMARY

However, in the technique disclosed in Non-Patent Document 1, since refresh is performed on the entire memory, there is a problem that more time is required for the refresh processing as the memory capacity increases, and thus the possibility that operation of the semiconductor device will be hindered by the refresh processing increases.

Other problems and novel features will become apparent from the description of this specification and the accompanying drawings.

In a semiconductor device and a method for controlling the same according to one embodiment, when there is an ECC error in data read from a read address indicated by a read request, an MRAM controller selectively performs, on the read address, refresh processing of writing back error-corrected data.

With the semiconductor device and the method for controlling the same according to one embodiment, by performing a selective refresh operation on a read address at which an error has occurred, the time required for refresh can be shortened, and the possibility that operation of the semiconductor device will be hindered can be reduced.

### BRIEF DESCRIPTION OF THE DRAWINGS

FIG. 1 is a block diagram schematically illustrating a semiconductor device according to a first embodiment.

FIG. 2 is a block diagram illustrating details of the semiconductor device according to the first embodiment.

FIG. 3 is a flowchart illustrating read processing of the semiconductor device according to the first embodiment.

FIG. 4 is a block diagram illustrating details of a semiconductor device according to a second embodiment.

FIG. 5 is a flowchart illustrating read processing of the semiconductor device according to the second embodiment.

FIG. 6 is a flowchart illustrating refresh processing of the semiconductor device according to the second embodiment.

FIG. 7 is a flowchart illustrating write processing of the semiconductor device according to the second embodiment.

FIG. 8 is a block diagram illustrating details of a semiconductor device according to a third embodiment.

FIG. 9 is a graph illustrating a principle for distinguishing hard error cells in the semiconductor device according to the third embodiment.

FIG. 10 is a table illustrating read results in distinguishing processing of hard error cells in the semiconductor device according to the third embodiment.

FIG. 11 is a flowchart illustrating read processing of the semiconductor device according to the third embodiment.

FIG. 12 is a flowchart illustrating redundant cell replacement processing of the semiconductor device according to the third embodiment.

FIG. 13 is a flowchart illustrating redundant cell replacement processing of a semiconductor device according to a fourth embodiment.

FIG. 14 is a table illustrating response contents for error bits in the semiconductor device according to the fourth embodiment.

FIG. 15 is a block diagram illustrating details of a semiconductor device according to a fifth embodiment.

FIG. 16 is a flowchart illustrating read processing of the semiconductor device according to the fifth embodiment.

FIG. 17 is a flowchart illustrating refresh processing of the semiconductor device according to the fifth embodiment.

FIG. 18 is a flowchart illustrating write-back processing of the semiconductor device according to the fifth embodiment.

FIG. 19 is a flowchart illustrating write-back processing of a semiconductor device according to a sixth embodiment.

FIG. 20 is a block diagram illustrating details of a semiconductor device according to a seventh embodiment.

FIG. 21 is a flowchart illustrating read processing of the semiconductor device according to the seventh embodiment.

FIG. 22 is a flowchart illustrating error address retention processing of the semiconductor device according to the seventh embodiment.

FIG. 23 is a flowchart illustrating refresh processing of the semiconductor device according to the seventh embodiment.

### DETAILED DESCRIPTION

For clarity of explanation, the following description and drawings are omitted and simplified as appropriate. In addition, each element illustrated in the drawings as a functional block that performs various processing can be configured by a CPU (Central Processing Unit), a memory, and other circuits in terms of hardware, and can be implemented by a program loaded into the memory in terms of software. Therefore, it is understood by those skilled in the art that these functional blocks can be realized in various forms by hardware only, software only, or a combination thereof, and are not limited to any one of them. In each drawing, the same elements are denoted by the same reference numerals, and redundant description is omitted as necessary.

In addition, the above-described program includes a group of instructions (or software code) for causing a computer to perform one or more functions described in the embodiments when the program is read into the computer. The program may be stored in a non-transitory computer-readable medium or a tangible storage medium. By way of example rather than limitation, the computer-readable medium or the tangible storage medium includes a random-access memory (RAM), a read-only memory (ROM), a flash memory, a solid-state drive (SSD), or other memory technology, a CD-ROM, a digital versatile disc (DVD), a Blu-ray (registered trademark) disc, or other optical disk storage, a magnetic cassette, magnetic tape, magnetic disk storage, or other magnetic storage device. The program may be transmitted on a transitory computer-readable medium or a communication medium. By way of example rather than limitation, the transitory computer-readable medium or the communication medium includes electrical, optical, acoustic, or other forms of propagated signals.

### First Embodiment

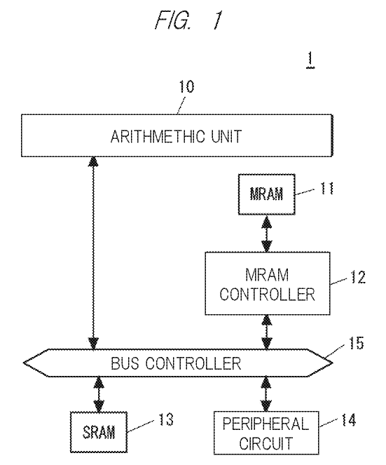

Hereinafter, embodiments of the present invention will be described with reference to the drawings. FIG. 1 is a block diagram illustrating an outline of a semiconductor device 1 according to a first embodiment. The semiconductor device according to the first embodiment is, for example, an MCU (Micro Controller Unit) in which an arithmetic unit, a memory, and a peripheral circuit are housed in one package. FIG. 1 illustrates, as an example of the semiconductor device 1, an MCU having an arithmetic unit 10, an MRAM (Magnetoresistive Random Access Memory) 11, an MRAM controller 12, an SRAM 13, a peripheral circuit 14, and a bus controller 15.

For example, the arithmetic unit 10 executes a program stored in the MRAM 11 to perform various processing defined by the program. The MRAM 11 is a storage unit that holds the program and data generated by arithmetic operations of the arithmetic unit 10. In the MRAM 11, a large number of MRAM cells are arranged, each bit constituting data is stored in each cell, and an access address is assigned to each item of data. The MRAM controller 12 issues specific commands for writing data to, or reading data from, the MRAM cells in the MRAM 11 based on a read command, a write command, a refresh command, and the like issued by the arithmetic unit 10. The MRAM controller 12 issues a write command when writing data to the MRAM 11, and issues a read command when reading data from the MRAM 11.

The SRAM 13 is a temporary storage device used in arithmetic processing of the arithmetic unit 10. The peripheral circuit 14 includes, for example, at least one circuit necessary for specifications of the semiconductor device 1, such as a timer, an input/output interface, and a communication interface. The bus controller 15 is a circuit that controls mutual communication among the arithmetic unit 10, the MRAM controller 12, the SRAM 13, and the peripheral circuit 14.

Since the semiconductor device 1 according to the first embodiment has one of its features in the configuration of the MRAM controller 12, a detailed description focusing on the MRAM controller 12 will be given below. Note that the semiconductor device 1 includes an ECC controller 22, which is not illustrated in FIG. 1, and the ECC controller 22 detects an ECC error in data output from the MRAM 11 (hereinafter, referred to as read data) and corrects the ECC error. Then, in the semiconductor device 1, refresh processing for writing the read data after ECC error correction (hereinafter, referred to as corrected data) back to the MRAM 11 is performed.

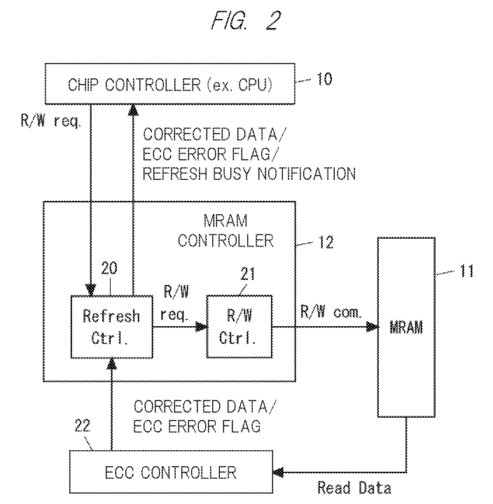

FIG. 2 is a block diagram illustrating details of the semiconductor device 1 according to the first embodiment. In the following description, an example is illustrated in which the arithmetic unit 10 is used as a chip controller that transmits a read request and a write request to the MRAM controller 12 and serves as a transmission destination of read data, corrected data, an ECC error flag, and a refresh busy notification output from the MRAM controller 12. Therefore, in the following description, the arithmetic unit 10 is referred to as a chip controller 10.

As illustrated in FIG. 2, in the semiconductor device 1, read data read from the MRAM 11 is transmitted to the ECC controller 22. Then, the ECC controller 22 checks whether an ECC error is present in the read data. When the ECC controller 22 determines that an ECC error is present, the ECC controller 22 corrects the ECC error and transmits corrected data to the MRAM controller 12. Further, when the read data includes an ECC error, the ECC controller 22 activates an ECC error flag to notify the MRAM controller 12 that the ECC error has occurred.

The MRAM controller 12 has a refresh controller 20 and a read/write controller 21. When the refresh controller 20 receives a read request and a write request from the chip controller 10, the refresh controller 20 transfers the received read request and write request to the read/write controller 21. Then, the read/write controller 21 transmits, to the MRAM 11, a read command using a read address included in the received read request as an access address. The MRAM 11 outputs, as read data, data held in an area specified by the read command. Further, the read/write controller 21 transmits, to the MRAM 11, a write command using a write address included in the received write request as an access address. Further, the write request includes write data, and the read/write controller 21 transmits the write address and the write data to the MRAM 11. The MRAM 11 writes the write data to the specified write address.

Further, the refresh controller 20 performs refresh processing. The refresh controller 20 performs the refresh processing when the refresh controller 20 learns, from an ECC error flag received from the ECC controller 22, that an ECC error has occurred in read data read from the read address specified by the read request. In this refresh processing, corrected data is written back to the area specified by the read address. That is, in the semiconductor device according to the first embodiment, refresh processing is selectively performed on the read address specified by the read request. More specifically, in the semiconductor device 1 according to the first embodiment, refresh processing is performed as part of read processing.

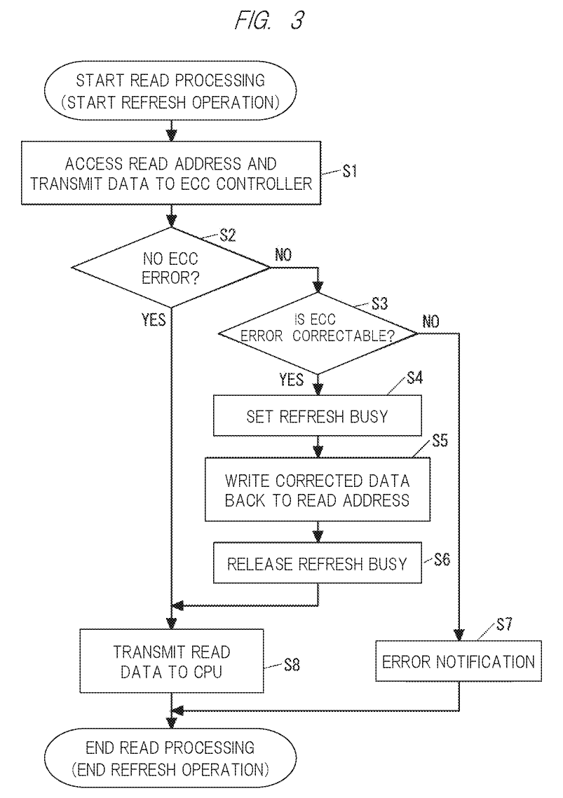

FIG. 3 is a flowchart illustrating read processing of the semiconductor device 1 according to the first embodiment. Note that the flowchart illustrated in FIG. 3 mainly illustrates operation of the MRAM controller 12 in the read processing.

As illustrated in FIG. 3, in the semiconductor device 1 according to the first embodiment, read processing is started when the chip controller 10 transmits a read request to the MRAM controller 12. In the read processing, the MRAM controller 12 accesses the read address and causes read data to be transmitted from the MRAM 11 to the ECC controller 22 (step S1). Subsequently, in the semiconductor device 1, the ECC controller 22 determines whether an ECC error is present in the read data (step S2).

Then, when it is determined in step S2 that no ECC error is present, the ECC controller 22 transmits the read data as it is to the refresh controller 20 while maintaining the ECC error flag in a no-error state (for example, 0). Then, the refresh controller 20 transmits the received read data to the chip controller 10 (step S8).

On the other hand, when it is determined in step S2 that an ECC error is present, the ECC controller 22 changes the ECC error flag to an error-present state (for example, 1), and determines whether the ECC error included in the read data is correctable (step S3). The error detection capability and the error correction capability of the ECC controller 22 are determined by specifications. For example, the capability of the ECC controller 22 is defined by the number of detectable errors and the number of correctable errors, such as being capable of 2-bit error detection and 1-bit error correction or being capable of 3-bit error detection and 2-bit error correction. That is, in step S3, when the number of detected errors is equal to or less than the error correction capability of the ECC controller 22, it is determined that ECC error correction is possible (the YES branch of step S3), and when the number of detected errors is greater than the error correction capability, it is determined that ECC error correction is not possible (the NO branch of step S3). Note that the number of detected errors is notified from the ECC controller 22 to the refresh controller 20, for example, as additional data of the error flag.

When the number of detected errors is greater than the error correction capability of the ECC controller 22, the refresh controller 20 transmits, to the chip controller 10, an error notification indicating that the MRAM 11 has failed (step S7).

On the other hand, when the number of detected errors is equal to or less than the error correction capability of the ECC controller 22, the refresh controller 20 performs refresh processing for writing corrected data back to the read address from which the corrected data has been read (step S5). Note that, while performing the refresh processing in step S5, the refresh controller 20 issues, to the chip controller 10, a refresh busy notification for setting a refresh busy state in order to prohibit the chip controller 10 from accessing the MRAM 11 (step S4). Further, in response to completion of the refresh processing in step S5, the refresh controller 20 notifies the chip controller 10 of release of the refresh busy state (step S6). After step S6, the refresh controller 20 transmits the corrected data to the chip controller 10 as read data (step S8).

From the above description, in the semiconductor device 1 according to the first embodiment, for read data including an ECC error, refresh processing for writing the data back after correcting the ECC error is performed. At this time, in the semiconductor device 1 according to the first embodiment, refresh processing is selectively performed on the read address at which the read data including the ECC error was stored. In this manner, by limiting the refresh processing to be performed in units of read addresses, in the semiconductor device 1 according to the first embodiment, the time required for refresh processing can be significantly reduced as compared with a case in which refresh processing is performed on the entirety of the MRAM 11. Then, by reducing the time required for refresh processing, the load required for refresh processing in the semiconductor device 1 can be reduced, and overall processing capability can be improved. Further, by performing refresh processing, it is possible to prevent the lifetime of the semiconductor device 1 from being shortened due to failure of the semiconductor device 1. Further, in the semiconductor device 1, corruption of data stored in the MRAM 11 can be corrected by performing refresh processing, and the period during which the performance of the semiconductor device 1 is maintained can be extended.

### Second Embodiment

In the second embodiment, an MRAM controller 12a, which is a modification of the MRAM controller 12 according to the first embodiment, will be described. Note that, in the description of the second embodiment, components described in the first embodiment are denoted by the same reference numerals as those in the first embodiment, and description thereof is omitted.

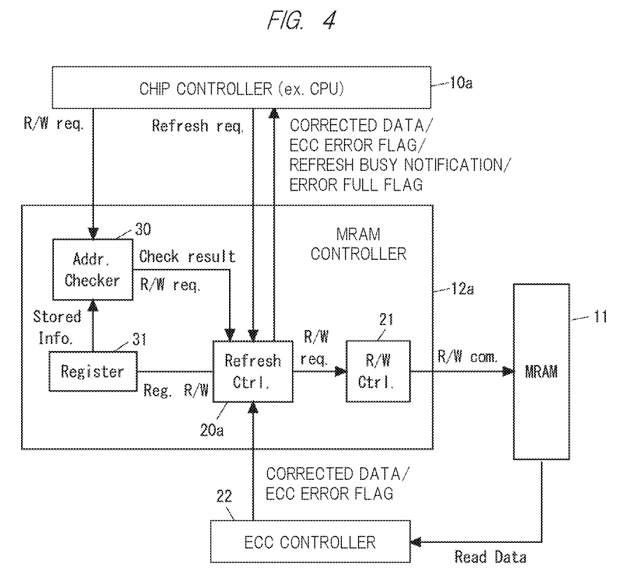

FIG. 4 is a block diagram illustrating details of the semiconductor device according to the second embodiment. As illustrated in FIG. 4, the semiconductor device according to the second embodiment has a chip controller 10a instead of the chip controller 10. The chip controller 10a is obtained by adding, to the chip controller 10, a function of outputting a refresh request based on a value of an error full flag output from the MRAM controller 12a described later. The chip controller 10a outputs a refresh request to the MRAM controller 12a in response to the error full flag becoming a value indicating that the amount of information held in a register 31 described later has reached a full state (for example, 1). Note that the chip controller 10a may have a function of outputting a refresh request at an arbitrary timing regardless of the value of the error full flag.

Further, as illustrated in FIG. 4, the semiconductor device according to the second embodiment has the MRAM controller 12a instead of the MRAM controller 12. The MRAM controller 12a is obtained by adding an address checker 30 and a register 31 to the MRAM controller 12. Further, the MRAM controller 12a has a refresh controller 20a instead of the refresh controller 20.

The address checker 30 performs address check processing for determining whether a read address included in a read request received from the chip controller 10a matches an error address held in the register 31. Then, when the address checker 30 determines that the read address and the error address do not match, the refresh controller 20a transmits the read request received via the address checker 30 to the read/write controller 21.

In the semiconductor device according to the second embodiment, the ECC controller 22 determines whether an ECC error is present in read data output from the MRAM 11 and performs error correction on the read data, as in the first embodiment. Then, in the second embodiment, when the refresh controller 20a determines, with reference to the ECC error flag, that the read data includes an ECC error, the refresh controller 20a sets, as an error address, the read address at which the read data determined to have the ECC error was stored, and stores the error address, corrected data, and an error count in association with one another. Further, when the error count stored in the register 31 reaches a preset specified number of times, the refresh controller 20a notifies the chip controller 10a of activation of an error full flag indicating that the error count has reached the specified number of times (for example, by updating a value from 0 to 1).

On the other hand, when the address checker 30 determines that the read address and the error address match, the refresh controller 20a transmits the corrected data stored in the register 31 to the chip controller 10a. More specifically, the refresh controller 20a transmits, to the chip controller 10a, corrected data stored in association with the error address matching the read address included in the read request.

Further, the address checker 30 performs address check processing for determining whether a write address included in a write request received from the chip controller 10a matches an error address held in the register 31. Then, when the address checker 30 determines that the write address and the error address do not match, the refresh controller 20a transmits the write request received via the address checker 30 to the read/write controller 21. As a result, data stored in the MRAM 11 is updated with data included in the write request.

On the other hand, when the address checker 30 determines that the write address and the error address match, the refresh controller 20a transmits the write request received via the address checker 30 to the read/write controller 21. As a result, data stored in the MRAM 11 is updated with data included in the write request. Then, in addition to the write processing in which the data in the MRAM 11 is updated based on the write request, the refresh controller 20a erases, from the corrected data stored in the register 31, corrected data stored in association with the error address matching the write address.

Next, operation of the semiconductor device according to the second embodiment will be described. Since read processing, refresh processing, and write processing are individually performed in the semiconductor device according to the second embodiment, operation of the semiconductor device will be described below for each processing.

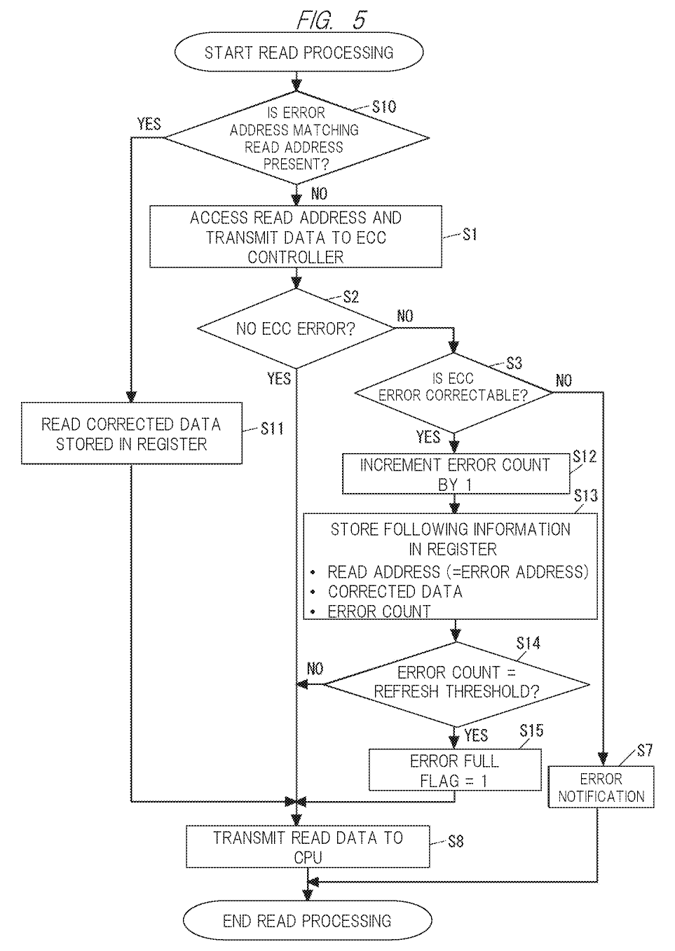

FIG. 5 is a flowchart illustrating read processing of the semiconductor device according to the second embodiment. In the second embodiment as well, read processing is started when the chip controller 10a transmits a read request to the address checker 30. In the semiconductor device according to the second embodiment, the address checker 30 determines whether an error address matching the read address is stored in the register 31 (step S10).

When it is determined in step S10 that an error address matching the read address is present, the refresh controller 20a reads, from the register 31, corrected data associated with the error address matching the read address (step S11). Thereafter, the refresh controller 20a transmits the corrected data read in step S11 to the chip controller 10a as read data (step S8).

On the other hand, when it is determined in step S10 that no error address matching the read address is present, the MRAM controller 12a accesses the read address and causes read data to be transmitted from the MRAM 11 to the ECC controller 22 (step S1). Subsequently, in the semiconductor device according to the second embodiment, the ECC controller 22 determines whether an ECC error is present in the read data (step S2).

Then, when it is determined in step S2 that no ECC error is preset, the ECC controller 22 transmits the read data as it is to the refresh controller 20a while maintaining the ECC error flag in a no-error state (for example, 0). Then, the refresh controller 20a transmits the received read data to the chip controller 10a (step S8).

On the other hand, when it is determined in step S2 that an ECC error is present, the ECC controller 22 changes the ECC error flag to an error-present state (for example, 1), and determines whether the ECC error included in the read data is correctable (step S3). When the number of detected errors is greater than the error correction capability of the ECC controller 22, the refresh controller 20a transmits, to the chip controller 10a, an error notification indicating that the MRAM 11 has failed (step S7).

On the other hand, when the number of detected errors is equal to or less than the error correction capability of the ECC controller 22, the refresh controller 20a increments the error count by one (step S12). In addition, the refresh controller 20a sets, as an error address, the read address received when the current read processing is started, and stores the error address, corrected data, and the error count in association with one another in the register 31 (step S13). Then, when the error count reaches a preset specified number of times (for example, a refresh threshold), the error full flag is updated from 0 to 1 (steps S14 and S15). On the other hand, when the error count is less than the refresh threshold, the error full flag is maintained at 0 (step S14). Thereafter, the refresh controller 20a transmits the corrected data to the chip controller 10a as read data (step S8).

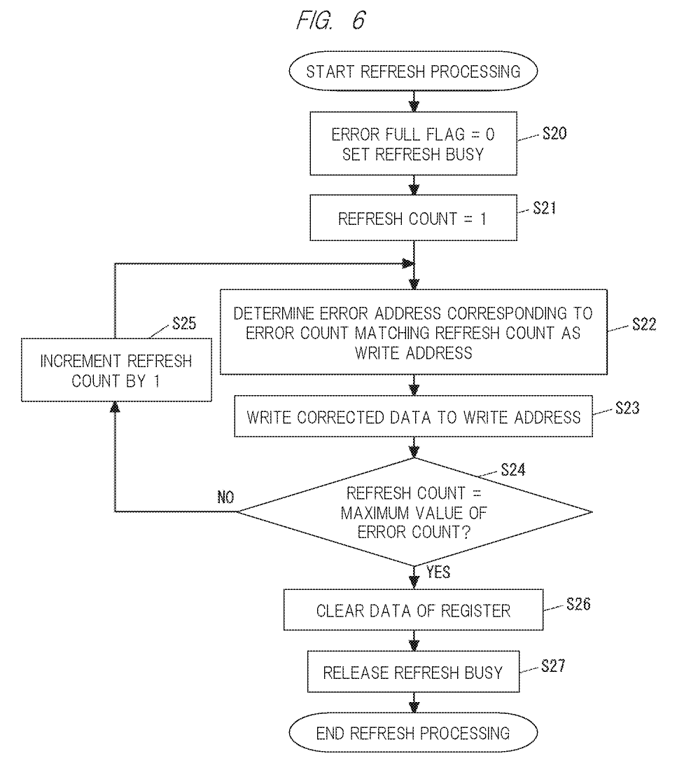

Next, refresh processing in the semiconductor device according to the second embodiment will be described. FIG. 6 is a flowchart illustrating refresh processing of the semiconductor device according to the second embodiment. In the semiconductor device according to the second embodiment, the refresh processing is started when the chip controller 10a transmits a refresh request to the refresh controller 20a in response to the error full flag being updated to 1.

In the refresh processing, in response to receiving the refresh request, the refresh controller 20a updates the error full flag from 1 to 0 and sets access to the MRAM 11 to a prohibited state by a refresh busy notification (step S20). In addition, the refresh controller 20a resets a refresh count used in internal processing to 1 (step S21).

Then, in the semiconductor device according to the second embodiment, the refresh controller 20a determines, as a write address, an error address corresponding to an error count matching the refresh count (step S22). Then, the refresh controller 20a writes corrected data stored in the register 31 to the write address determined in step S22 (step S23). By the write processing in step S23, data stored in an area corresponding to the error address is overwritten with correct data. Then, in the semiconductor device according to the second embodiment, the processing of steps S22 and S23 is repeated until the refresh count reaches a maximum value of the error count, while incrementing the refresh count by one (steps S24 and S25).

After the refresh count reaches the maximum value of the error count, the refresh controller 20a clears the data in the register 31 (step S26). In addition, the refresh controller 20a notifies the chip controller 10a that the refresh busy state is released (step S27).

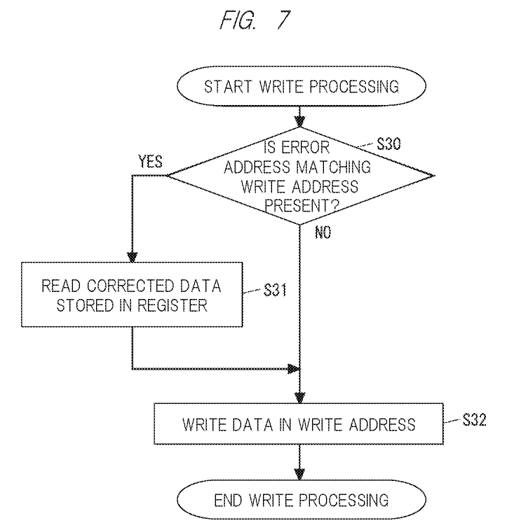

Next, write processing in the semiconductor device according to the second embodiment will be described. FIG. 7 is a flowchart illustrating write processing of the semiconductor device according to the second embodiment. In the semiconductor device according to the second embodiment, the write processing is started when the chip controller 10a transmits a write request to the address checker 30.

In the write processing, first, the address checker 30 determines whether an error address matching the write address is stored in the register 31 (step S30). Then, when it is determined in step S30 that an error address matching the write address is present, the refresh controller 20a clears, from the register 31, corrected data associated with the error address matching the write address (step S31). Thereafter, the refresh controller 20a writes data received together with the write request to the write address of the MRAM 11 (step S32).

On the other hand, when it is determined in step S30 that no error address matching the write address is present, the MRAM controller 12a writes data received together with the write request to the write address of the MRAM 11 (step S32).

From the above description, in the semiconductor device according to the second embodiment, data in which an ECC error has occurred is corrected and then temporarily held in the register 31. Then, the semiconductor device according to the second embodiment performs refresh processing when the amount of corrected data accumulated in the register 31 reaches a specified amount. In this refresh processing, as in the first embodiment, refresh processing is selectively performed on error addresses, so that the refresh processing can be completed in a short time.

Further, in the semiconductor device according to the second embodiment, since the refresh operation is not performed until the corrected data is accumulated up to the specified amount, it is possible to reduce a period during which the processing load of the semiconductor device reaches an upper limit by taking measures such as allocating, to idle time of processing in the semiconductor device, a time during which access of the semiconductor device to the MRAM 11 is prohibited.

### Third Embodiment

In the third embodiment, an MRAM controller 12b, which is a modification of the MRAM controller 12 according to the first embodiment, will be described. Note that, in the description of the third embodiment, components described in the first embodiment are denoted by the same reference numerals as those in the first embodiment, and description thereof is omitted.

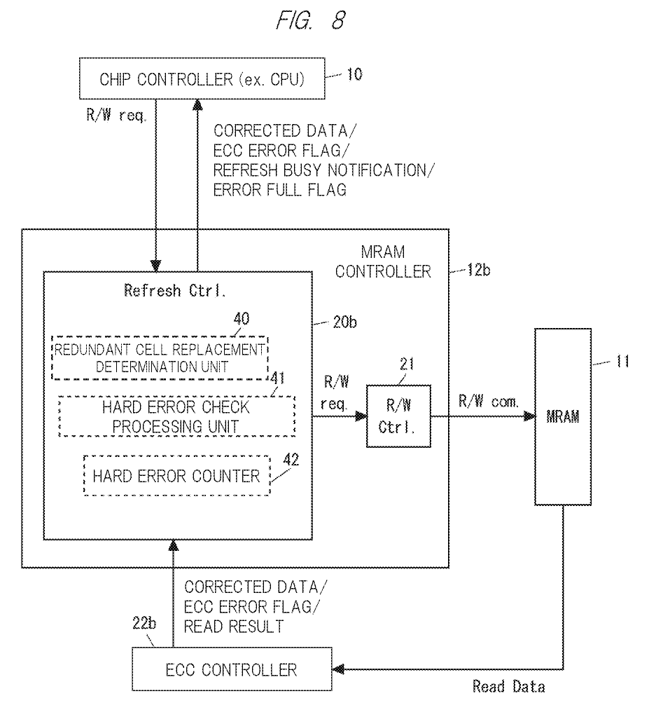

FIG. 8 is a block diagram illustrating details of the semiconductor device according to the third embodiment. As illustrated in FIG. 8, the semiconductor device according to the third embodiment has an MRAM controller 12b instead of the MRAM controller 12. Further, the semiconductor device according to the third embodiment has an ECC controller 22b instead of the ECC controller 22. The ECC controller 22b is obtained by adding, to the ECC controller 22, a function of outputting information of an error bit as a read result.

The MRAM controller 12b is obtained by replacing the refresh controller 20 of the MRAM controller 12 with a refresh controller 20b. The refresh controller 20b is obtained by adding, to the refresh controller 20, a redundant cell replacement determination unit 40, a hard error check processing unit 41, and a hard error counter 42.

The redundant cell replacement determination unit 40 performs redundant cell replacement determination processing in which an MRAM cell belonging to a read address determined to have a hardware error is replaced with a redundant cell prepared in advance, and corrected data is then written back to the redundant cell. That is, in the third embodiment, the MRAM 11 includes redundant cells that are spare MRAM cells in addition to MRAM cells used from the start of use.

When there is an ECC error, the hard error check processing unit 41 performs hard error check processing for checking whether a hardware error has occurred in an MRAM cell belonging to the read address at which the ECC error has occurred.

The hard error counter 42 counts, for each read address, the number of hardware errors as a hard error counter value.

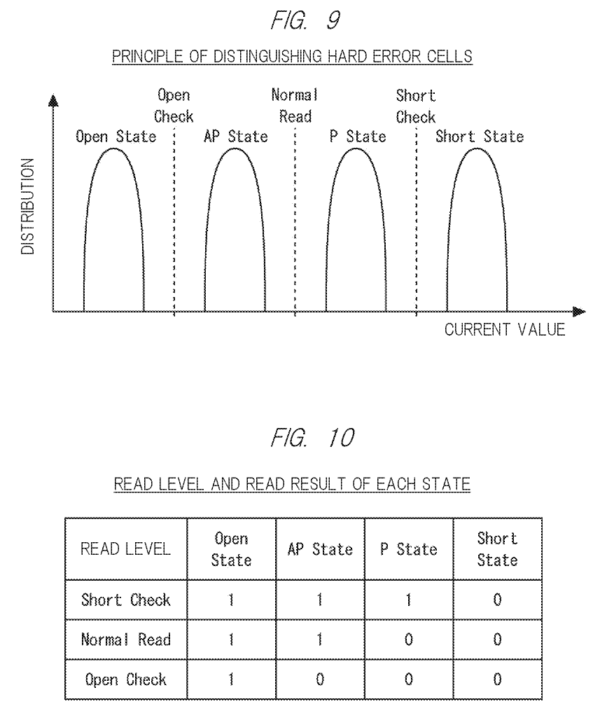

Here, hard error check processing performed by the hard error check processing unit 41 will be described in detail. FIG. 9 is a graph illustrating a principle for distinguishing hard error cells in the semiconductor device according to the third embodiment. In the graph illustrated in FIG. 9, the horizontal axis represents a current value drawn into an MRAM cell when read processing is performed on the MRAM cell, and the vertical axis represents a distribution of occurrence frequencies of the current value drawn into the MRAM cell.

As illustrated in FIG. 9, an MRAM cell exhibits distinctive characteristics in a current value drawn thereinto depending on a stored value and a failure mode. Specifically, in an open state in which the MRAM cell is in an insulated state, the current value is smaller than that in an AP state in which 1 is stored. Also, the current value in the AP state is smaller than that in a P state in which 0 is stored. Further, the current value in the P state is smaller than that in a short state in which a short-circuit failure has occurred in the MRAM cell. The hard error check processing unit 41 performs read processing on an error bit notified by a read result, and determines, from the current value at that time, whether failure of the MRAM cell is caused by a hardware error or is a soft failure in which a bit value is inverted. More specifically, as illustrated in FIG. 9, since differences occur in current values drawn in the open state, the AP state, the P state, and the short state, thresholds of current values separating the respective states are set as an open check level, a normal read level, and a short check level. Then, the hard error check processing unit 41 performs hardware check processing based on the threshold range in which the current value obtained during read processing of the MRAM cell falls, and the value output as the read result.

FIG. 10 is a table illustrating read results in distinguishing processing of hard error cells in the semiconductor device according to the third embodiment. As illustrated in FIG. 10, when the read result is 0 and the current value is greater than the short check level, the hard error check processing unit 41 determines that a hardware error due to a short-circuit failure has occurred in the MRAM cell. When the read result is 1 and the current value is equal to or less than the open check level, the hard error check processing unit 41 determines that a hardware error due to an open failure has occurred. Further, when the current value is equal to or greater than the normal read level and less than the short check level, or when the current value is less than the normal read level and greater than the open check level, the hard error check processing unit 41 determines that a soft error has occurred in the MRAM cell.

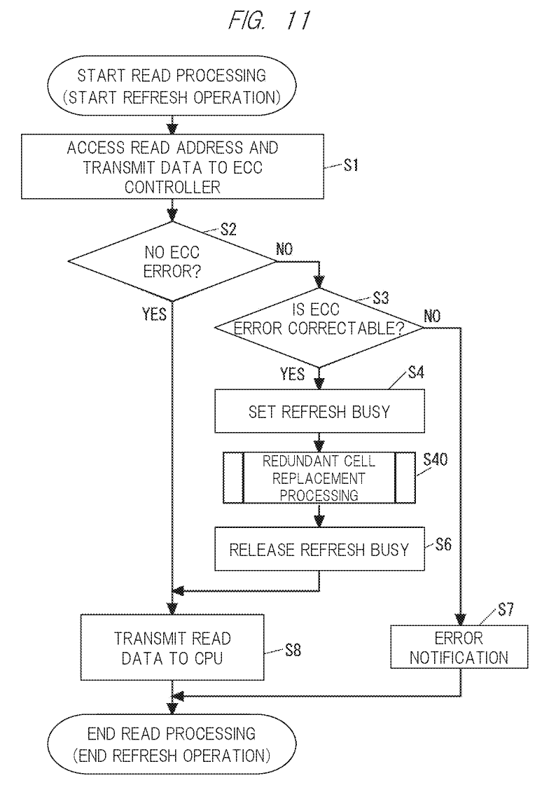

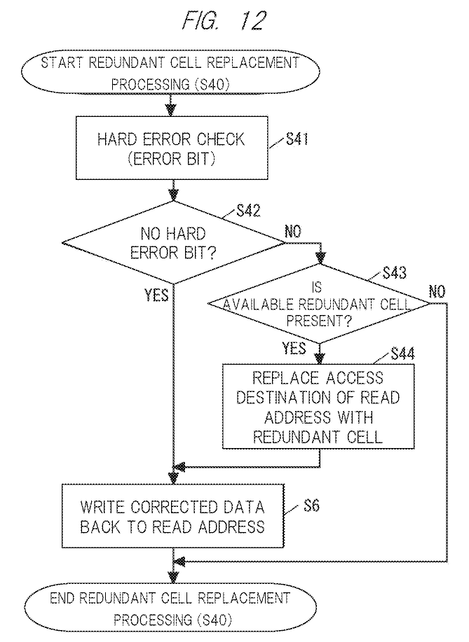

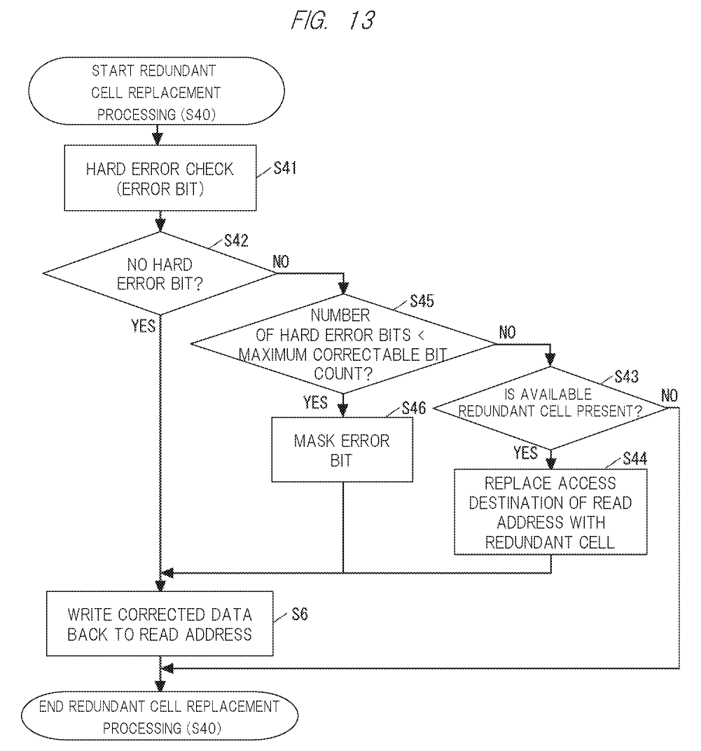

In the semiconductor device according to the third embodiment, refresh processing for overwriting data in which the error has occurred with corrected data is performed for a soft error, and replacement with a redundant cell is performed for a hardware error. Thus, operation of the semiconductor device according to the third embodiment will be described with reference to FIGS. 11 and 12 .

FIG. 11 is a flowchart illustrating read processing of the semiconductor device according to the third embodiment. As illustrated in FIG. 11, in the third embodiment, redundant cell replacement processing (step S40) is performed instead of refresh processing (step S5) described with reference to FIG. 3 of the first embodiment. FIG. 12 is a flowchart illustrating redundant cell replacement processing of the semiconductor device according to the third embodiment.

In the semiconductor device according to the third embodiment, when notification that an ECC error has occurred is received from the ECC controller 22b, the refresh controller 20b performs redundant cell replacement processing. In this redundant cell replacement processing, as illustrated in FIG. 12, first, the hard error check processing unit 41 performs hard error check processing on an error bit (step S41). The hard error bit is identified from information of a bit in which an error has occurred, the information being indicated by a read result output from the ECC controller 22b. Then, when it is determined in the hard error check processing that no hard error bit is present (the YES branch of step S42), the ECC controller 22b performs refresh processing for writing corrected data back to the read address from which the corrected data was read (step S6).

On the other hand, when it is determined in the hard error check processing that a hard error bit is present (the NO branch of step S42), the redundant cell replacement determination unit 40 determines whether an available redundant cell is present (step S43). When the redundant cell replacement determination unit 40 determines that an available redundant cell is present (the YES branch of step S43), the redundant cell replacement determination unit 40 replaces, with the redundant cell, an access destination based on the read address from which the corrected data was read (step S44). Thereafter, the ECC controller 22b performs refresh processing for writing corrected data back to the read address for which the access destination was switched in step S44 (step S6). On the other hand, when the redundant cell replacement determination unit 40 determines that no available redundant cell is present (the NO branch of step S43), the redundant cell replacement processing is ended without performing the replacement processing for replacing the MRAM cell with the redundant cell of step S44 and the refresh processing of step S6.

An ECC error occurring due to hardware failure cannot be recovered by refresh processing based on corrected data. However, in the semiconductor device according to the third embodiment, the hardware failure can be substantially recovered by replacing an MRAM cell in which a hardware error has occurred with a redundant cell.

Further, in the semiconductor device according to the third embodiment, when no available redundant cell is present, corrected data corrected by the ECC controller 22b is returned to the chip controller 10a, thereby enabling continuous use of the hardware.

### Fourth Embodiment

In the fourth embodiment, another example of the redundant cell replacement processing according to the third embodiment will be described. In the fourth embodiment, the ECC controller 22b has a function of performing 3-bit error detection and 2-bit error correction. Further, in the fourth embodiment, the hard error counter 42 included in the refresh controller 20b counts the number of hardware errors for each read address as a hard error count value.

Then, in the semiconductor device according to the fourth embodiment, when the hard error count value is less than a preset maximum correctable bit count, the refresh controller 20b masks an error bit in which a hardware error has occurred and writes corrected data back. Further, in response to the hard error count value reaching the preset maximum correctable bit count, the refresh controller 20b replaces an MRAM cell belonging to a read address determined to have a hardware error with a redundant cell prepared in advance, and then writes corrected data back to the redundant cell.

FIG. 13 is a flowchart illustrating redundant cell replacement processing of the semiconductor device according to the fourth embodiment. As illustrated in FIG. 13, in the redundant cell replacement processing according to the fourth embodiment, in the flow illustrated in FIG. 13, processing of steps S45 and S46 is performed after a hard error bit is detected (the NO branch of step S42) and before an MRAM cell including the error bit is replaced with a redundant cell (steps S43 and S44).

In step S45, the redundant cell replacement determination unit 40 reads the hard error count value from the hard error counter 42 and determines whether the number of hard error bits is less than the maximum correctable bit count (for example, 2 bits) (step S45).

When it is determined in step S45 that the number of hard error bits is less than the maximum correctable bit count, the ECC controller 22b masks the error bit (step S46), and then performs refresh processing for writing corrected data back to the read address (step S6). On the other hand, when the redundant cell replacement determination unit 40 determines in step S45 that the number of hard error bits is equal to or greater than the maximum correctable bit count, replacement processing for replacing an access destination of the read address with a redundant cell is performed if an available redundant cell is present (steps S43 and S44).

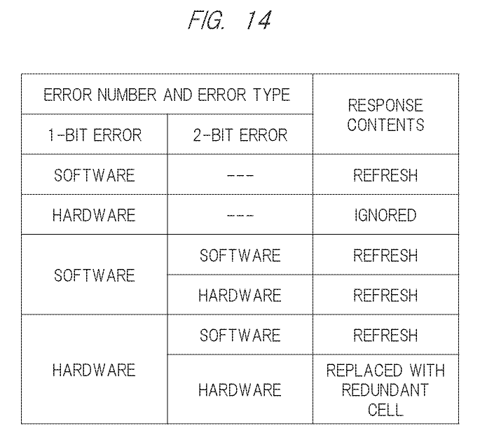

Here, response contents for error bits in the fourth embodiment will be described with reference to a table. FIG. 14 is a table illustrating response contents for error bits in the semiconductor device according to the fourth embodiment. As illustrated in FIG. 14, in the semiconductor device according to the fourth embodiment, when a 1-bit error is a soft error, refresh processing is performed, and when a 1-bit error is a hardware error, the error is ignored and read data whose error is corrected by an error correction function of the ECC controller 22b is used.

Further, when a 1-bit error is a soft error, recovery processing by refresh processing is performed regardless of whether a 2-bit error is a hard error or a soft error. Further, when a 1-bit error is a hardware error, refresh processing is performed if a 2-bit error is a soft error, and redundant cell replacement processing is performed if a 2-bit error is a hardware error.

From the above description, in the fourth embodiment, by suppressing use of redundant cells as compared with the semiconductor device according to the third embodiment, it becomes possible to extend a usable period of the semiconductor device as compared with the third embodiment.

### Fifth Embodiment

In the fifth embodiment, an MRAM controller 12c, which is a modification of the MRAM controller 12b according to the third embodiment, will be described. Note that, in the description of the fifth embodiment, components described in the first to third embodiments are denoted by the same reference numerals as those in the first to third embodiments, and description thereof is omitted.

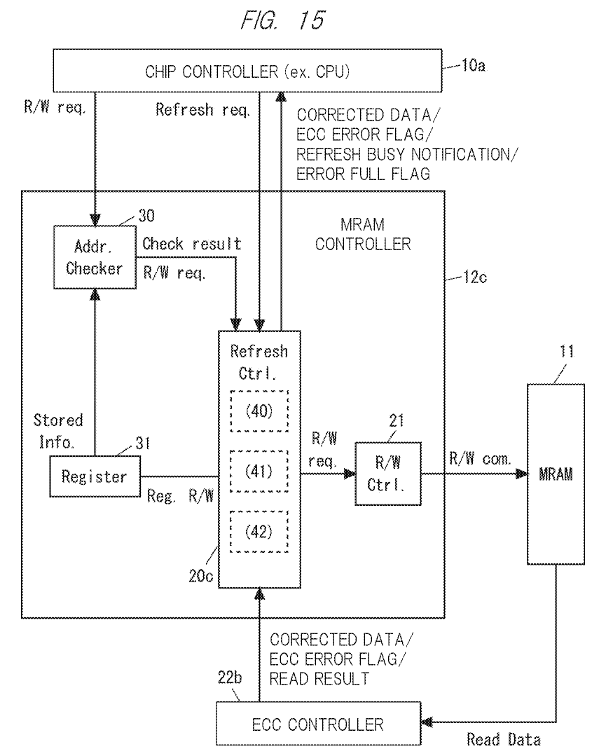

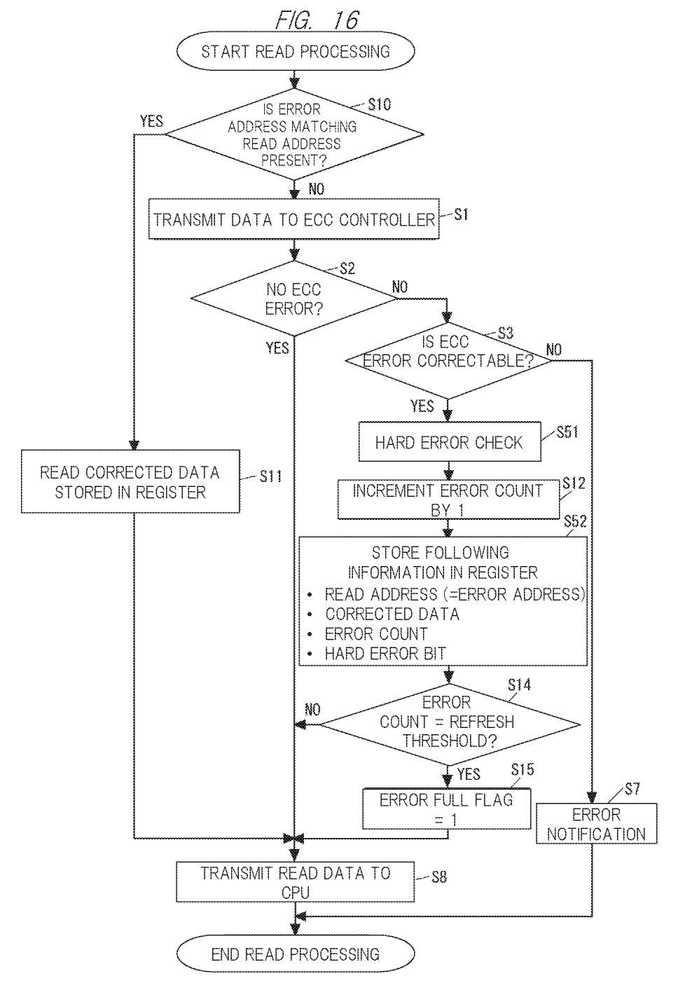

FIG. 15 is a block diagram illustrating details of the semiconductor device according to the fifth embodiment. As illustrated in FIG. 15, the semiconductor device according to the fifth embodiment has an MRAM controller 12c obtained by adding the address checker 30 and the register 31 described in the second embodiment to the MRAM controller 12b illustrated in FIG. 8. Further, the MRAM controller 12c is obtained by replacing the refresh controller 20b with a refresh controller 20c. The refresh controller 20c performs read processing while storing, in the register 31, error information including a result of hard error check processing performed by the hard error check processing unit 41, and performs refresh processing including redundant cell replacement processing after the number of pieces of error information stored in the register 31 reaches a specified number.

FIG. 16 is a flowchart illustrating read processing of the semiconductor device according to the fifth embodiment. As illustrated in FIG. 16, the semiconductor device according to the fifth embodiment performs processing in which step S51 is added to the processing described with reference to FIG. 5 and step S13 is replaced with step S52. In step S51, the hard error check processing unit 41 performs hard error check processing on an error bit based on a read result obtained from the ECC controller 22b. Further, in the semiconductor device according to the fifth embodiment, information of the hard error bit obtained in the hard error check processing of step S51 is included in the error information stored in the register 31 in step S52. More specifically, in the fifth embodiment, the register 31 includes at least information on an error address, corrected data, an error count (number of error information stored in the register 31), and a hard error bit.

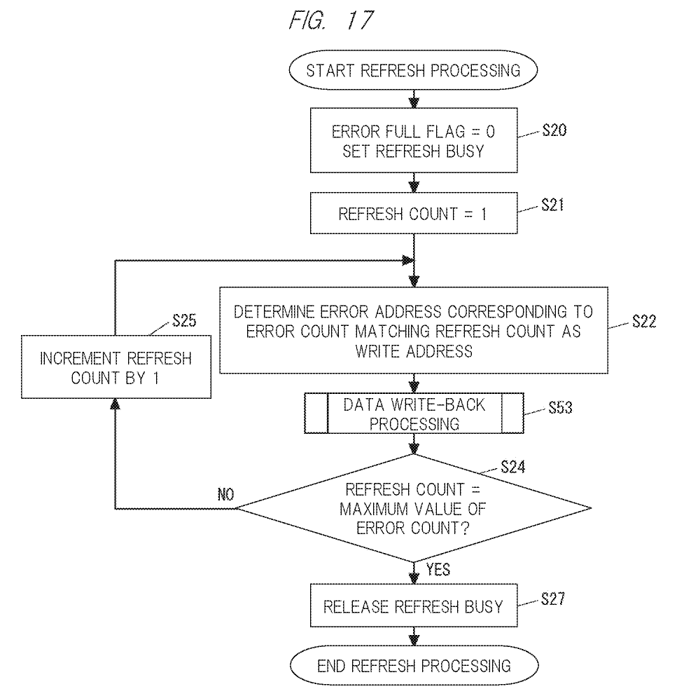

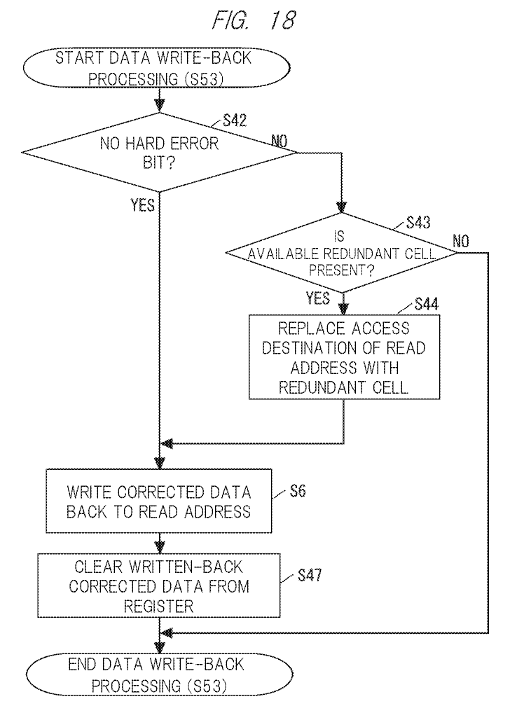

Next, FIG. 17 is a flowchart illustrating refresh processing of the semiconductor device according to the fifth embodiment. As illustrated in FIG. 17, in the refresh processing of the semiconductor device according to the fifth embodiment, the processing of step S6 in the second embodiment described with reference to FIG. 6 is replaced with data write-back processing of step S53. Further, in the refresh processing of the semiconductor device according to the fifth embodiment, register clearing processing of step S26 in FIG. 6 is performed in the data write-back processing. Here, FIG. 18 is a flowchart illustrating write-back processing of the semiconductor device according to the fifth embodiment.

In the semiconductor device according to the fifth embodiment, hard error check processing is performed in the read processing, and hard-error-bit information is stored in the register 31. Therefore, as illustrated in FIG. 18, in the semiconductor device according to the fifth embodiment, redundant cell replacement processing in which the hard error check processing (step S41) of the third embodiment illustrated in FIG. 12 is omitted is performed as the data write-back processing (step S53). Further, in the write-back processing (step S53) of the fifth embodiment, after corrected data is written back to the read address in step S6 (step S6), the written-back corrected data is cleared from the register (step S47). By clearing only the written-back data from the register in this manner, data that could not be written back can still be read from the register thereafter.

From the above description, the semiconductor device according to the fifth embodiment has the MRAM controller 12c in which the MRAM controller 12b is adapted to addition of the address checker 30 and the register 31. As a result, in the semiconductor device according to the fifth embodiment, as in the second embodiment, it is possible to reduce a period during which the processing load of the semiconductor device reaches an upper limit by taking measures such as allocating, to idle time of processing in the semiconductor device, a time during which access of the semiconductor device to the MRAM 11 is prohibited. Further, in the semiconductor device according to the fifth embodiment, as in the third embodiment, it is possible to extend a usable period of the semiconductor device by performing the redundant cell replacement processing.

### Sixth Embodiment

In the sixth embodiment, an example will be described in which the same change as that made by changing the redundant cell replacement processing according to the third embodiment to the redundant cell replacement processing according to the fourth embodiment is applied to the semiconductor device according to the fifth embodiment.

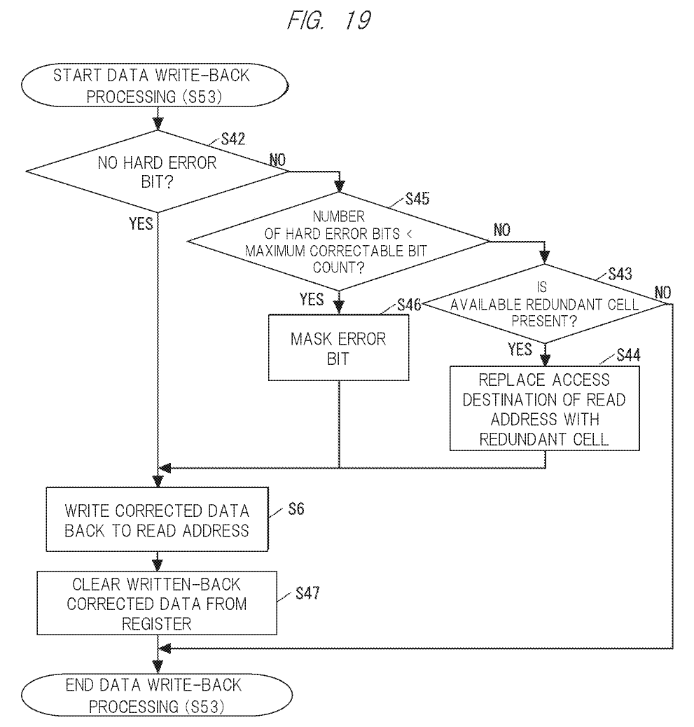

FIG. 19 is a flowchart illustrating write-back processing of the semiconductor device according to the sixth embodiment. As illustrated in FIG. 19, data write-back processing (step S53) according to the sixth embodiment is obtained by omitting the hard error check processing (step S41) from the redundant cell replacement processing (step S40) according to the fourth embodiment described with reference to FIG. 13. Further, in the sixth embodiment as well, the written-back corrected data is cleared from the register after step S6 (step S47).

In this manner, the data write-back processing according to the fifth embodiment can also be made compatible with multi-bit errors.

### Seventh Embodiment

In the seventh embodiment, an MRAM controller 12d, which is a modification of the MRAM controller 12b according to the third embodiment, will be described. Note that, in the description of the seventh embodiment, components described in the first to third embodiments are denoted by the same reference numerals as those in the first to third embodiments, and description thereof is omitted.

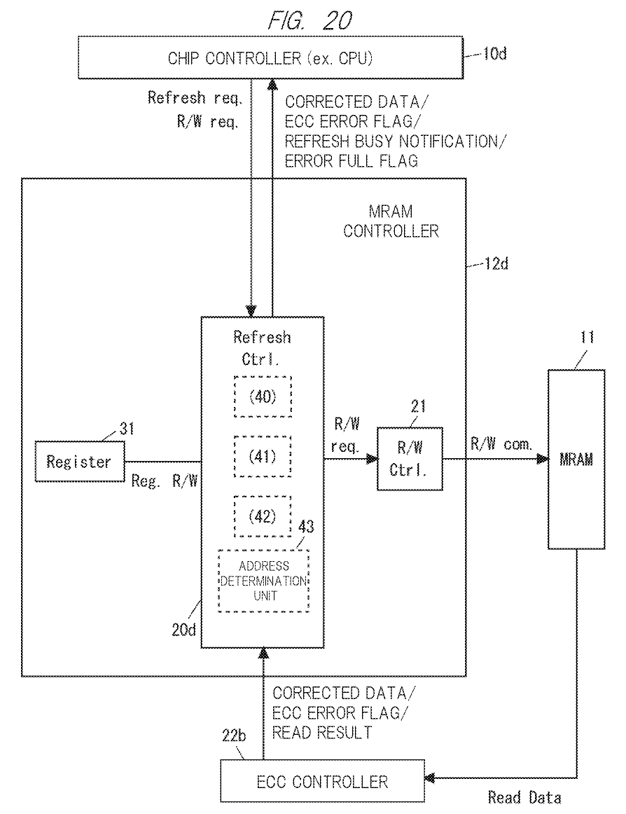

FIG. 20 is a block diagram illustrating details of the semiconductor device according to the seventh embodiment. As illustrated in FIG. 20, the semiconductor device according to the seventh embodiment is obtained by replacing the MRAM controller 12b according to the third embodiment with an MRAM controller 12d. Further, the MRAM controller 12d is obtained by adding the register 31 to the MRAM controller 12b. The refresh controller 20d is obtained by adding an address determination unit 43 to the refresh controller 20b. Note that the semiconductor device according to the seventh embodiment has a chip controller 10d in which input and output information is changed from that of the chip controller 10a in accordance with changes of the MRAM controller 12d.

The refresh controller 20d is obtained by adding the address determination unit 43 to the refresh controller 20c. When a read address at which data determined to include an ECC error was stored is smaller than a start address stored in the register, the address determination unit 43 updates the start address with the read address smaller than the start address. Further, when the read address at which the data determined to include the ECC error was stored is greater than an end address stored in the register, the address determination unit 43 updates the end address with the read address greater than the end address. Update processing of the start address and the end address performed by the address determination unit 43 may also be referred to as address determination processing.

In the seventh embodiment, the register 31 holds a start address serving as a start position and an end address serving as an end position of a range of read addresses for which refresh processing is performed.

Then, in the refresh processing, the MRAM controller 12d performs read processing for reading data by issuing read commands from the start address toward the end address. Further, when the ECC controller 22b determines that there is an ECC error in the data, the MRAM controller 12d performs refresh processing for writing error-corrected data back.

Further, when there is an ECC error, the MRAM controller 12d causes the hard error check processing unit 41 to perform hard error check processing for checking whether a hardware error has occurred in an MRAM cell belonging to the read address at which the ECC error has occurred. Further, the MRAM controller 12d causes the redundant cell replacement determination unit 40 to perform redundant cell replacement determination processing for replacing the MRAM cell belonging to the read address determined to have a hardware error with a redundant cell prepared in advance and then writing corrected data back to the redundant cell.

Further, the MRAM controller 12d counts, in the hard error counter 42, the number of hardware errors for each read address as a hard error count value. Then, when the hard error count value is less than a preset maximum correctable bit count, the MRAM controller 12d performs data write-back processing for masking an error bit in which a hardware error has occurred and then writing corrected data back. Further, in response to the hard error count value reaching the preset maximum correctable bit count, the MRAM controller 12d performs data write-back processing for replacing an MRAM cell belonging to a read address determined to have a hardware error with a redundant cell prepared in advance and then writing corrected data back to the redundant cell.

That is, in the semiconductor device according to the seventh embodiment, refresh processing including redundant cell replacement processing is performed on a certain range of memory area including a read address at which data including an ECC error is stored.

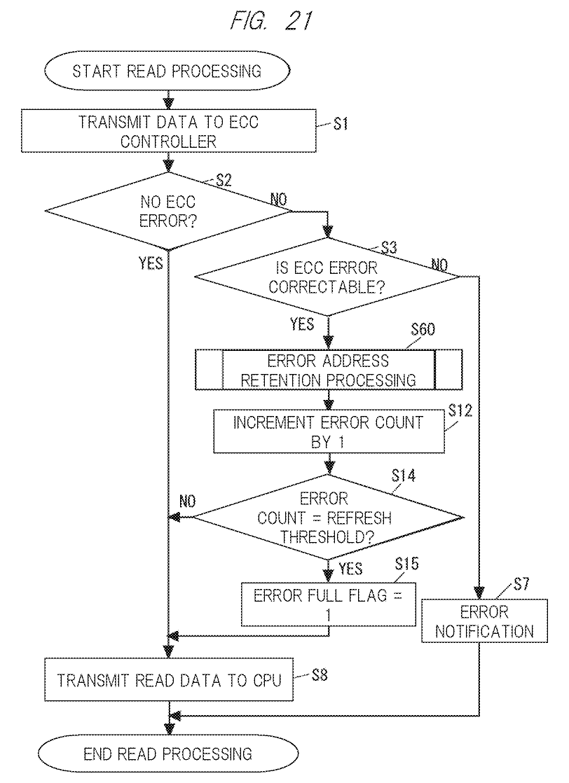

FIG. 21 is a flowchart illustrating read processing of the semiconductor device according to the seventh embodiment. As illustrated in FIG. 21, in the semiconductor device according to the seventh embodiment, refresh processing of steps S4 to S6 in the read processing of the semiconductor device according to the first embodiment illustrated in FIG. 3 is replaced with steps S60, S12, S14, and S15. Step S60 is error address retention processing performed when there is read data in which a correctable ECC error has occurred (the YES branch of step S3). Details of the error address retention processing will be described later.

In the seventh embodiment, after performing the error address retention processing (step S60), the refresh controller 20d increments the error count by one (step S12). Here, in the seventh embodiment, the refresh controller 20d does not set, as an error address, the read address received when the current read processing is started, and does not store the error address, corrected data, and the error count in association with one another in the register 31. Then, when the error count reaches a preset number of times (for example, a refresh threshold), the refresh controller 20d updates the error full flag from 0 to 1 (steps S14 and S15). On the other hand, when the error count is less than the refresh threshold, the error full flag is maintained at 0 (step S14). Thereafter, the refresh controller 20d transmits the corrected data to the chip controller 10 as read data (step S8).

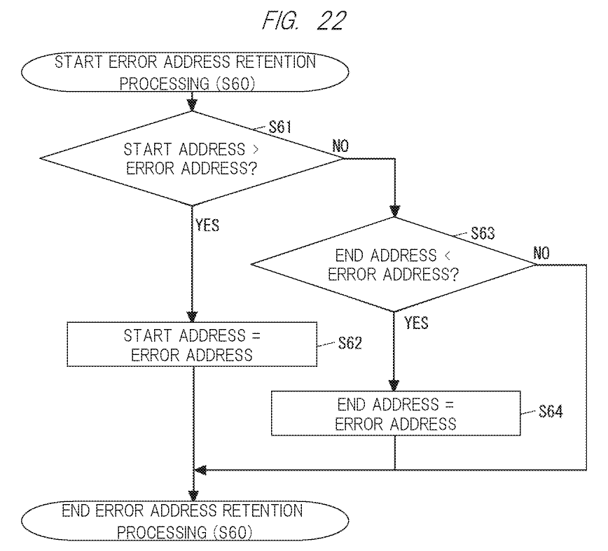

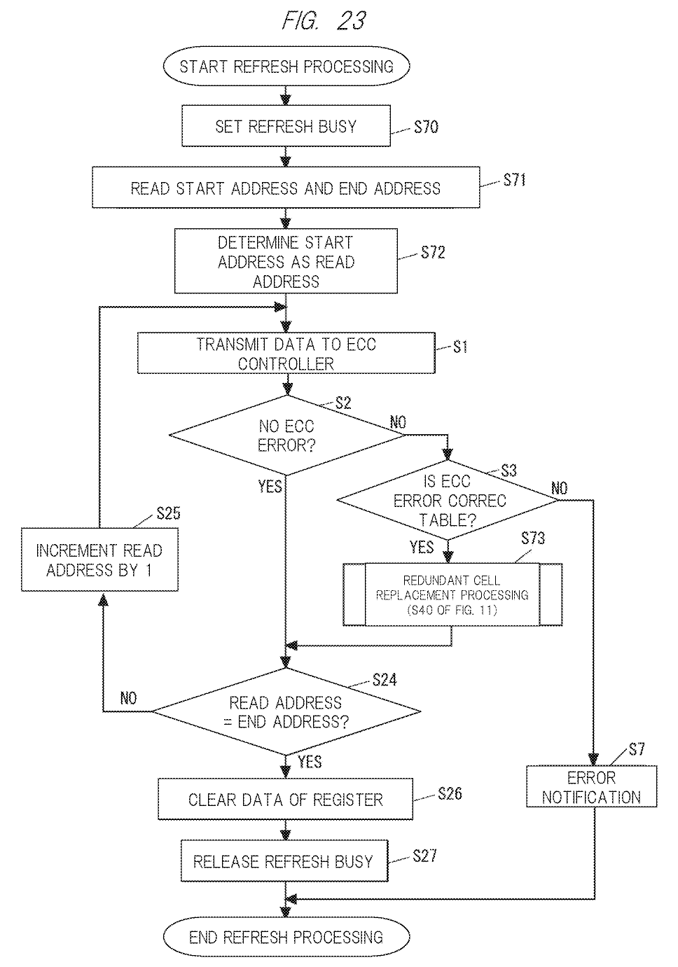

Here, error address retention processing (step S60) performed by the address determination unit 43 will be described. FIG. 22 is a flowchart illustrating error address retention processing of the semiconductor device according to the seventh embodiment. The start address and the end address illustrated in FIG. 22 are values held in the register 31. In an initial state in which no ECC error has been detected, for example, the largest read address in a memory area is set as the start address. In an initial state in which no ECC error has been detected, for example, the smallest read address in the memory area is set as the end address.

As illustrated in FIG. 22, in the error address retention processing, first, when the error address is smaller than the start address held in the register 31, the address determination unit 43 updates the start address with the error address at that time (steps S61 and S62). On the other hand, when the error address is equal to or greater than the start address held in the register 31, the address determination unit 43 compares the end address with the error address (step S63). When the error address is greater than the end address held in the register 31, the address determination unit 43 updates the end address with the error address at that time (step S64). On the other hand, when the address determination unit 43 determines in step S63 that the error address is equal to or less than the end address held in the register 31, the address determination unit 43 ends the error address retention processing without updating the start address and the end address.

Next, refresh processing according to the seventh embodiment based on the start address and the end address will be described. FIG. 23 is a flowchart illustrating refresh processing of the semiconductor device according to the seventh embodiment.

As illustrated in FIG. 23, in the seventh embodiment, the refresh processing is started when the chip controller 10d transmits a refresh request to the MRAM controller 12d. Upon receiving the refresh request, the MRAM controller 12d sets refresh busy (step S70). Thereafter, the MRAM controller 12d reads the start address and the end address from the register 31 (step S71). Then, the MRAM controller 12d determines the start address as a first read address (step S72).

Thereafter, the MRAM controller 12d issues a read request to the MRAM 11 using the read address, and causes read data to be transmitted from the MRAM 11 to the ECC controller 22b (step S1). The ECC controller 22b checks whether an ECC error is present in the read data (step S2). When it is determined in step S2 that no ECC error is present, the MRAM controller 12d repeats the operations of steps S1 and S2 while incrementing the read address by one until the read address reaches the end address (steps S24 and S25). Note that, after the read address reaches the end address (the YES branch of step S24), the MRAM controller 12d clears the data in the register 31 (step S26), releases refresh busy (step S27), and ends the refresh processing.

On the other hand, when an ECC error is detected in step S2, the MRAM controller 12d checks whether the ECC error is correctable (step S3). When it is determined in step S3 that the ECC error cannot be corrected, the MRAM controller 12d issues an error notification to the chip controller 10d and ends the refresh processing (step S7). When it is determined in step S3 that the ECC error can be corrected, the MRAM controller 12d performs data write processing using the redundant cell replacement determination unit 40 (step S73). The data write processing of step S73 is, for example, the same processing as the redundant cell replacement processing (step S40) illustrated in FIG. 11. Specific processing of step S40 may be the redundant cell replacement processing according to the third embodiment illustrated in FIG. 12, or may be the redundant cell replacement processing according to the fourth embodiment illustrated in FIG. 13.

From the above description, in the seventh embodiment, a plurality of read addresses including an error address and a read address at which data including no error is stored is set as a target area for refresh processing, and refresh processing is performed on the target area. This makes it possible to reduce a capacity of the register 31 in the semiconductor device according to the seventh embodiment.

Note that the present invention is not limited to the above embodiments, and can be modified as appropriate within the range not departing from the gist thereof.

What is claimed is:

1. A semiconductor device comprising:
a storage unit in which MRAM (Magnetoresistive Random Access Memory) cells are arranged;
an MRAM controller configured to transmit a read command and a write command to the storage unit;
a chip controller configured to transmit a read request and a write request to the MRAM controller; and
an ECC controller configured to determine whether data read from the storage unit has an ECC error and to perform error correction on the data,
wherein, when the data read from a read address specified by the read request has the ECC error, the MRAM controller selectively performs refresh processing of writing back the data after error correction on the read address.

2. The semiconductor device according to claim 1,
wherein the MRAM controller sets, as an error address, the read address at which data determined to have the ECC error was stored, and includes a register configured to hold the error address, the data after error correction, and an error count in association with one another,
wherein the MRAM controller performs address check processing for determining whether the read address specified by the read request received from the chip controller matches the error address held in the register, and
wherein, when the read address matches the error address, the MRAM controller transmits the data after error correction stored in the register to the chip controller.

3. The semiconductor device according to claim 2,
wherein, when the error count stored in the register has reached a preset specified number of times, the MRAM controller notifies the chip controller of activation of an error full flag indicating that the error count has reached the specified number of times,
wherein the chip controller transmits a refresh request to the MRAM controller at an arbitrary timing, and
wherein, in response to receiving the refresh request, the MRAM controller performs refresh processing of writing back the data after error correction stored in the register to the error address.

4. The semiconductor device according to claim 2,
wherein the chip controller transmits a refresh request to the MRAM controller at an arbitrary timing, and
wherein, in response to receiving the refresh request, the MRAM controller performs refresh processing of writing back the data after error correction stored in the register to the error address.

5. The semiconductor device according to claim 2,
wherein the MRAM controller performs:
hard error check processing for checking whether a hardware error has occurred in an MRAM cell belonging to the read address at which the ECC error has occurred when the ECC error is present; and
redundant cell replacement determination processing for replacing the MRAM cell belonging to the read address determined to have the hardware error with a redundant cell prepared in advance and then writing the data after error correction back to the redundant cell.

6. The semiconductor device according to claim 5, further comprising a hard error counter configured to count, for each read address, the number of the hardware errors as a hard error count value,
wherein the MRAM controller masks an error bit in which the hardware error has occurred and then writes back the data after error correction when the hard error count value is less than a preset maximum correctable bit count, and
wherein, in response to the hard error count value reaching the preset maximum correctable bit count, the MRAM controller replaces the MRAM cell belonging to the read address determined to have the hardware error with a redundant cell prepared in advance and then writes the data after error correction back to the redundant cell.

7. The semiconductor device according to claim 1,
wherein the MRAM controller performs:
hard error check processing for checking whether a hardware error has occurred in an MRAM cell belonging to the read address at which the ECC error has occurred when the ECC error is present; and
redundant cell replacement determination processing for replacing the MRAM cell belonging to the read address determined to have the hardware error with a redundant cell prepared in advance and then writing the data after error correction back to the redundant cell.

8. The semiconductor device according to claim 7, further comprising a hard error counter configured to count, for each read address, the number of the hardware errors as a hard error count value,
wherein the MRAM controller masks an error bit in which the hardware error has occurred and then writes back the data after error correction when the hard error count value is less than a preset maximum correctable bit count, and
wherein, in response to the hard error count value reaching the preset maximum correctable bit count, the MRAM controller replaces the MRAM cell belonging to the read address determined to have the hardware error with a redundant cell prepared in advance and then writes the data after error correction back to the redundant cell.

9. The semiconductor device according to claim 1,
wherein the MRAM controller includes a register configured to hold a start address serving as a start position and an end address serving as an end position of a range of the read addresses for which the refresh processing is performed,
wherein the MRAM controller performs address determination processing for updating the start address with the read address smaller than the start address when the read address at which data determined to have the ECC error was stored is smaller than the start address stored in the register, and updating the end address with the read address greater than the end address when the read address at which the data determined to have the ECC error was stored is greater than the end address stored in the register,
wherein the MRAM controller performs read processing for reading the data by issuing the read command from the start address toward the end address, and
wherein the MRAM controller performs the refresh processing of writing back the data after error correction when the ECC controller determines that the data has the ECC error.

10. The semiconductor device according to claim 9,
wherein the MRAM controller performs:
hard error check processing for checking whether a hardware error has occurred in an MRAM cell belonging to the read address at which the ECC error has occurred when the ECC error is present; and
redundant cell replacement determination processing for replacing the MRAM cell belonging to the read address determined to have the hardware error with a redundant cell prepared in advance and then writing the data after error correction back to the redundant cell.

11. The semiconductor device according to claim 10, further comprising a hard error counter configured to count, for each read address, the number of the hardware errors as a hard error count value,
wherein the MRAM controller masks an error bit in which the hardware error has occurred and then writes back the data after error correction when the hard error count value is less than a preset maximum correctable bit count, and
wherein, in response to the hard error count value reaching the preset maximum correctable bit count, the MRAM controller replaces the MRAM cell belonging to the read address determined to have the hardware error with a redundant cell prepared in advance and then writes the data after error correction back to the redundant cell.

12. A method for controlling a semiconductor device, the semiconductor device including:
a storage unit in which MRAM (Magnetoresistive Random Access Memory) cells are arranged;
an MRAM controller configured to transmit a read command and a write command to the storage unit;
a chip controller configured to transmit a read request and a write request to the MRAM controller; and
an ECC controller configured to determine whether data read from the storage unit has an ECC error and to perform error correction on the data,
wherein, when the data read from a read address specified by the read request has the ECC error
, the MRAM controller selectively performs refresh processing of writing back the data after error correction on the read address.
